(19) United States
(12) Patent Application Publication
(10) Pub. No.: US 2014/0008642 A1
(43) Pub. Date: Jan. 9, 2014

(54) INK COMPOSITION, ORGANIC EL DEVICE USING INK COMPOSITION, AND METHOD FOR PRODUCING ORGANIC EL DEVICE

(71) Applicant: Toppan Printing Co., Ltd., Tokyo (JP)

(72) Inventors: Takayuki Morita, Tokyo (JP); Takuma Oouchi, Tokyo (JP); Tomohiro Kai, Tokyo (JP); Yoshihiro Suzuki, Tokyo (JP)

(73) Assignee: Toppan Printing Co., Ltd., Tokyo (JP)

(21) Appl. No.: 14/026,786

(22) Filed: Sep. 13, 2013

Related U.S. Application Data
(63) Continuation of application No. PCT/JP2012/056312, filed on Mar. 12, 2012.

(30) Foreign Application Priority Data
Mar. 29, 2011 (JP) 2011-073331

(51) Int. Cl. C09K 11/02; H01L 51/56; H01L 51/50

(52) U.S. Cl. CPC C09K 11/02; H01L 51/50; H01L 51/56
USPC 257/40; 252/301.35; 438/46

(57) ABSTRACT

An ink composition that is capable of forming a low molecular weight luminescent material having no repeating structure into a favorable film within a partition wall by coating by a nozzle printing method, an organic EL device using the ink composition, and the method for producing the organic EL device are to be provided. The ink composition is used for forming an organic luminescent medium layer of an organic EL device by a nozzle printing method, in which an organic luminescent layer as one of the organic layer contains a low molecular weight luminescent material that has no repeating structure and a polymer material having a repeating structure, which are mixed with each other, and the polymer material is a nonconductive material.

### CROSS-REFERENCE TO RELATED APPLICATION

This application is a continuation of International Application No. PCT/JP2012/056312, filed Mar. 12, 2012, which is incorporated herein by reference.

### BACKGROUND OF THE INVENTION

1. Field of the Invention

The present invention utilizes an electroluminescence (which may be hereinafter abbreviated as EL) phenomenon of an organic thin film, and relates to an ink composition containing an organic EL material, an organic EL device using the ink composition, and a method for producing the organic EL device.

2. Related Art

An organic EL device has a conductive organic luminescent layer, and an anode and a cathode disposed on both sides of the organic luminescent layer in the width direction of the organic luminescent layer, and is produced by forming, on a light transmissive substrate, an anode, an organic luminescent layer and a cathode in this order. A voltage is applied to the organic luminescent layer to inject electrons and positive holes for recombination, and the organic luminescent layer emits light on the recombination. For such purposes as enhancement of the luminescent efficiency of the organic luminescent layer, a hole transporting layer may be provided between the anode and the organic luminescent layer, and an electron transporting layer may be provided between the cathode and the organic luminescent layer, in some cases.

In general, the organic luminescent layer, the hole transporting layer and the electron transporting layer are formed with a polymer material that has a large molecular weight and is well soluble in a solvent. Accordingly, the layers may be formed by a wet coating method under the atmospheric pressure, such as a spin coating method, and a printing method, such as a relief printing method and a relief reverse offset printing method (see, for example, JP-A-2003-17248 and JP-A-2004-296226), an ink-jet method (see, for example, JP-A-2004-296226, Japanese Patent No. 3,541,625 and JP-A-2009-267299), and a nozzle printing method (see, for example, JP-A-2001-189192), which realizes reduction of the cost for production equipments and enhancement of the productivity.

A low molecular weight luminescent material used in an organic luminescent layer has a luminescent efficiency and a lifetime that are better than a polymer luminescent material, and there is a demand of replacement of the polymer luminescent material with the low molecular weight luminescent material. However, in the production method of an organic EL device by the aforementioned wet coating method requires partition of pixels with a partition wall for providing RGB pixels in the luminescent layer, which derives a problem due to the film forming property of the low molecular weight luminescent material within the pixels. Specifically, a film formed of the low molecular weight luminescent material has such a tendency that the surface of the film has a convex shape, which causes unevenness in luminescence, and thus the luminescent efficiency and the lifetime may be deteriorated.

### SUMMARY OF THE INVENTION

An object of the invention is to solve the problems described above, and to provide an ink composition that is capable of forming a favorable coated film of a low molecular weight luminescent material within a partition wall, an organic EL device using the ink composition, and a method for producing the organic EL device.

According to a first embodiment of the invention, an ink composition for forming an organic layer of an organic EL device is provided, in which an organic luminescent layer as one of the organic layer contains at least one low molecular weight luminescent material that has no repeating structure and at least one polymer material having a repeating structure, which are mixed with each other, the polymer material is a nonconductive material, and a weight ratio of the nonconductive polymer material with respect to the low molecular weight luminescent material is from 0.001 to 0.05.

According to a second embodiment of the invention, in the ink composition of the first embodiment, the nonconductive polymer material has a weight average molecular weight of from 10,000 to 1,000,000.

According to a third embodiment of the invention, in the ink composition of the first embodiment, the nonconductive polymer material has a glass transition point of 100° C. or more.

According to a fourth embodiment of the invention, in the ink composition of the first embodiment, the nonconductive polymer material is polystyrene, polymethyl methacrylate or polycarbonate.

According to a fifth embodiment of the invention, an organic EL device is provided that contains an anode, a cathode and plural organic layers intervening between the anode and the cathode, an organic luminescent layer as one of the organic layers containing at least one of a low molecular weight luminescent material that has no repeating structure and at least one of a polymer material having a repeating structure, which are mixed with each other, the polymer material being a nonconductive material, and a weight ratio of the nonconductive polymer material with respect to the low molecular weight luminescent material being from 0.001 to 0.05.

According to a sixth embodiment of the invention, in the organic EL device of the fifth embodiment, the nonconductive polymer material has a weight average molecular weight of from 10,000 to 1,000,000.

According to a seventh embodiment of the invention, in the organic EL device of the fifth embodiment, the nonconductive polymer material has a glass transition point of 100° C. or more.

According to an eighth embodiment of the invention, in the organic EL device of the fifth embodiment, the nonconductive polymer material is polystyrene, polymethyl methacrylate or polycarbonate.

According to a ninth embodiment of the invention, a method for producing an organic EL device is provided that contains: a coating step of coating the ink composition according to any one of the first to fourth embodiments by a nozzle printing method on a device substrate partitioned into pixels with a partition wall; and a solvent removing step of removing an ink solvent contained in the ink composition according to anyone of the first to fourth embodiments to form an organic layer for the organic EL device.

According to a tenth embodiment of the invention, in the method for producing an organic EL device of the ninth embodiment, the solvent removing step contains a drying step of heating in a nitrogen atmosphere at a heating temperature of 100° C. or more.

According to the ink composition, the organic EL device using the ink composition, and the method for producing the organic EL device of the invention, a stable organic luminescent layer may be formed as a flat film while preventing the materials from being aggregated in the drying step due to the binding effect of the polymer material.

The use of the nonconductive polymer material as an additive enables favorable coating and film formation of the low molecular weight luminescent material without deterioration of the carrier balance.

### BRIEF DESCRIPTION OF THE DRAWINGS

FIG. 1 is a schematic cross-sectional view showing a structure of an organic EL device according to an embodiment of the invention.

FIG. 2 is a schematic cross-sectional view showing a nozzle printing apparatus according to an embodiment of the invention.

FIG. 3 is a schematic perspective view showing a nozzle printing apparatus according to an embodiment of the invention.

FIG. 4 is a cross-sectional view explaining a flatness of a pixel of an organic EL device according to an embodiment of the invention.

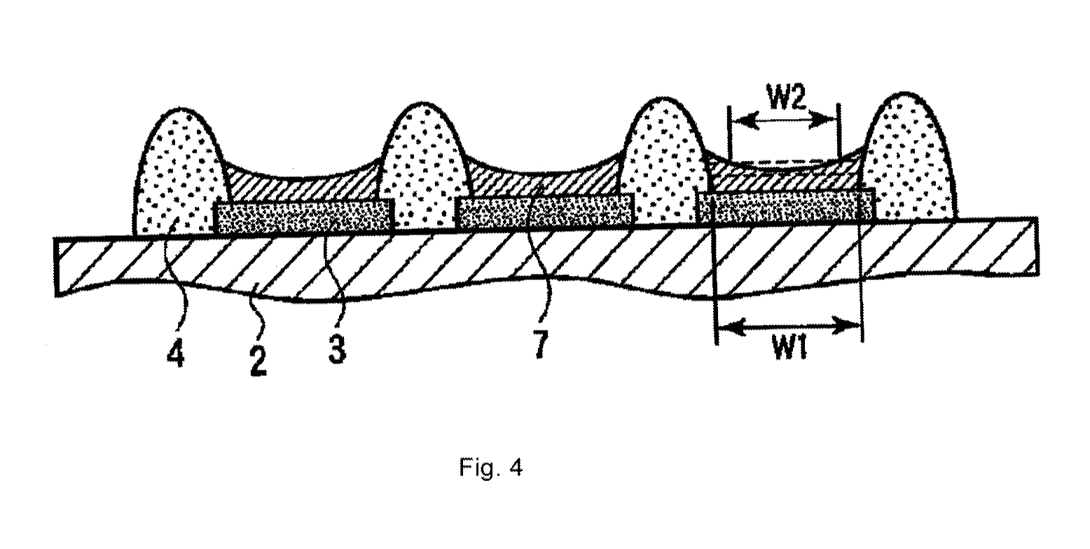

### DESCRIPTION OF THE EMBODIMENTS

Embodiments of the invention will be described with reference to attached drawings.

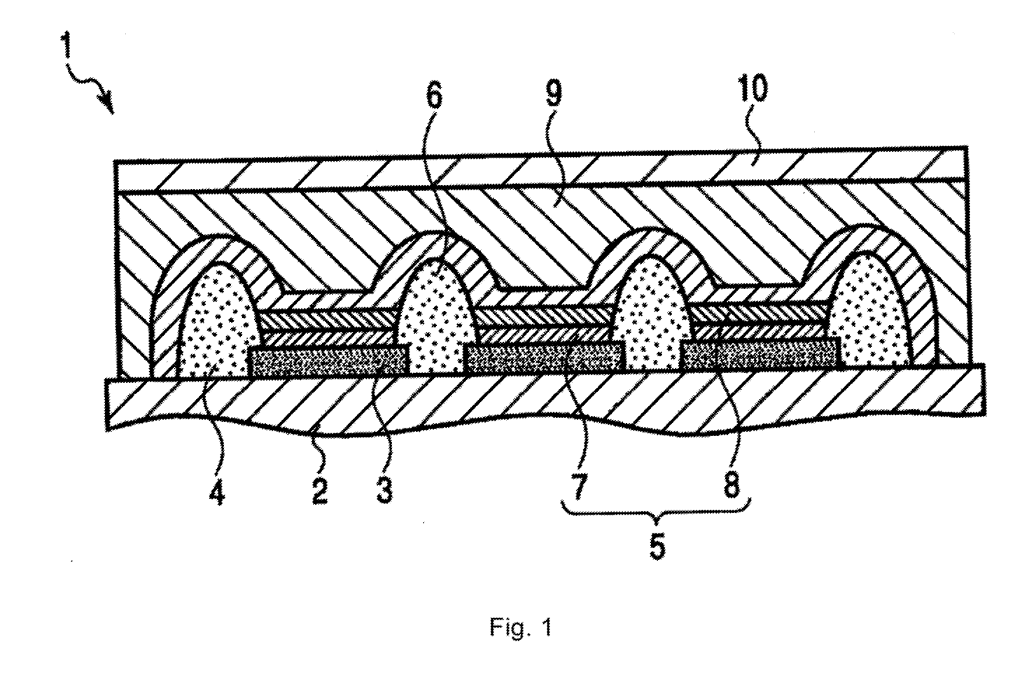

FIG. 1 is a schematic cross-sectional view showing a structure of an organic EL device according to an embodiment of the invention. The organic EL device 1 according to the embodiment is an organic EL device that has a so-called active matrix structure, and contains a light transmissive substrate 2 having a thin film transistor (TFT) formed thereon, plural pixel electrodes 3 that are formed on one surface of the light transmissive substrate 2, a partition wall 4 that partitions linearly the pixel electrodes 3, an organic luminescent medium layer 5 that is accumulated on the pixel electrode 3, and a counter electrode 6 that is accumulated on the organic luminescent medium layer 5 and is disposed to face the pixel electrode 3. The case where the pixel electrode 3 is an anode and the counter electrode 6 is a cathode will be described below.

The organic EL device 1 according to the embodiment may have a so-called passive matrix structure, and may have a pixel electrode as a cathode and a counter electrode as an anode.

The light transmissive substrate 2 is a substrate that supports the pixel electrode 3, the organic luminescent medium layer 5 and the counter electrode 6, and may be formed of a film or a sheet of a metal, glass, plastics or the like. Examples of the plastic film used include films of polyethylene terephthalate, polypropylene, cycloolefin polymer, polyamide, polyether sulfone, polymethylmethacrylate and polycarbonate.

The light transmissive substrate 2 may have, on the other surface thereof having no pixel electrode 3 formed thereon, a gas barrier film, such as a ceramics vapor-deposited film, a polyvinylidene chloride film, a polyvinyl chloride film, an ethylene-vinyl acetate copolymer saponified product film, laminated thereon.

The light transmissive substrate 2 in the embodiment may be an active-driven substrate having a thin film transistor (TFT) formed thereon. In the case where an active-driven organic EL device is to be formed as a printed matter in the embodiment, it is preferred that a flattening layer is formed on the TFT, a lower electrode of the organic EL device is formed on the flattening layer, and the TFT and the lower electrode are electrically connected with a contact hole provided in the flattening layer.

According to the structure, excellent electric insulation may be provided between the TFT and the organic EL device. The TFT and the organic EL device provided above the TFT are supported by a supporting member. The supporting member preferably has excellent mechanical strength and dimensional stability, and examples of the supporting member include those described for the substrate above. The thin film transistor formed on the supporting member may be any known thin film transistor.

Specific examples of the thin film transistor include a thin film transistor mainly having an active layer having a source/drain region and a channel region formed therein, a gate dielectric film and a gate electrode. The structure of the thin film transistor is not particularly limited, and examples thereof include known structures, such as a staggered type, an inverted staggered type, a top gate type, a bottom gate type and a coplanar type. Alight transmissive substrate is necessarily used for a bottom emission organic EL device, but the substrate is not limited to a light transmissive substrate for a top emission type organic EL device.

A layer formed of a material of the pixel electrode 3 is formed on the substrate and then may be patterned depending on necessity. The layer formed of a material of the pixel electrode 3 is partitioned with the partition wall 4 to constitute the pixel electrode 3 corresponding to each of pixels. Examples of the material of the pixel electrode 3 include a metal composite oxide, such as ITO (indium tin composite oxide), indium zinc composite oxide and zinc aluminum composite oxide, a metal material, such as gold and platinum, and a fine particle dispersion film containing fine particles of the metal oxide or the metal material dispersed in a resin, such as an epoxy resin and an acrylic resin, and these materials may be used in the form of a single layer or a multilayer structure.

In the case where the pixel electrode is used as an anode, a material that has a large work function, such as ITO, is preferably selected. A material that has light transmissibility is necessarily selected for the so-called bottom emission structure. An auxiliary electrode of a metal material, such as copper and aluminum, may also be provided for reducing the wiring resistance of the pixel electrode. The optimum thickness of the pixel electrode 3 may vary depending on the structure of the organic EL device constituting a display device, and may be from 100 to 10,000 Å, and preferably from 100 to 3,000 Å, irrespective of the single layer structure or the multilayer structure.

Examples of the forming method of the pixel electrode 3 include a dry film forming method, such as a resistance heating vapor deposition method, an electron beam vapor deposition method, a reactive vapor deposition method, an ion plating method and a sputtering method, and a wet film forming method, such as a gravure printing method and a screen printing method, which may be selected depending on the material.

The partition wall 4 is formed to cover edges of the pixel electrodes 3 for preventing the organic luminescent medium layers 5 formed on the pixel electrodes 3 from being mixed with each other, and the pattern of the partition wall 4 is preferably a lattice pattern or a linear pattern that partitions the pixel electrodes 3. In the case where the organic luminescent layer is formed by a nozzle printing method, the partition wall is preferably formed in a linear form that is in parallel to the luminescent layers of the same luminescent color to partition the luminescent layers of different colors, and in this case, the partition wall is formed to cover only two edges of the pixel electrodes 3.

Examples of the forming method of the partition wall 4 include ordinary methods, such as a method of forming an inorganic film over the entire surface of the substrate, masking the film with a resist, and then dry-etching the film, and a method of accumulating a photosensitive resin on a substrate and forming a given pattern by a photolithography method. A method including a combination of the methods may also be used, for example, a photosensitive resin layer may be formed on an inorganic film, or an inorganic film may be accumulated on a photosensitive resin layer, followed by patterning, thereby forming a partition wall having a multilayer structure. Furthermore, liquid repellency to the ink may be imparted to the partition wall by adding a liquid repellent agent to the material or by irradiating the partition wall with a plasma or an ultraviolet ray.

Examples of the photosensitive resin that may be used as a material for the partition wall 4 include a polyimide resin, an acrylic resin and a novolac resin, and any resin that is applied to a photolithography method may be used. Examples of the inorganic material include SiO₂, SiN and SiON.

The partition wall 4 preferably has a height of from 0.1 to 10 μm, and more preferably from 0.5 to 2 μm. When the height of the partition wall 4 exceeds 10 μm, the formation and sealing of the counter electrode may be impaired, and when the height thereof is less than 0.1 μm, the partition wall 4 may fail to cover the edges of the pixel electrode 3 completely, or the organic luminescent medium layer may form a short circuit or may cause color mixing with the adjacent pixel on forming the layer.

Subsequently, the organic luminescent medium layer 5 is formed as an organic functional thin film in the embodiment. The organic luminescent medium layer 5 in the embodiment may be a single layer film or a multilayer film that contains an organic luminescent material, and may have a laminated structure containing at least a hole transporting layer 7 formed on the pixel electrode 3 and an organic luminescent layer 8 formed on the hole transporting layer 7.

Preferred examples of the multilayer structure include a two-layer structure containing a hole transporting layer and an electron transporting luminescent layer, a two-layer structure containing a hole transporting luminescent layer and an electron transporting layer, a three-layer structure containing a hole transporting layer, an organic luminescent layer and an electron transporting layer, and multilayer structures obtained by dividing the hole or electron injection function and the hole or electron transporting function and inserting a layer that blocks transportation of holes or electrons. The organic luminescent layer referred herein means a layer that contains an organic luminescent material.

The hole transporting layer 7 has a function of directing holes injected from the pixel electrode 3 as an anode to the counter electrode 6 as a cathode, and preventing electrons from being directed to the pixel electrode 3 while transmitting holes.

Examples of a hole transporting material used in the hole transporting layer 7 include a metal phthalocyanine compound, such as copper phthalocyanine and tetra(t-butyl) copper phthalocyanine, a metal-free phthalocyanine compound, a quinacridone compound, an aromatic amine low molecular weight hole injection-transporting material, such as 1,1-bis (4-di-p-tolylaminophenyl)cyclohexane, N,N′-diphenyl-N,N′-bis(3-methylphenyl)-1,1′-biphenyl-4,4′-diamine and N,N′-di(1-naphthyl)-N,N′-diphenyl-1,1′-biphenyl-4,4′-diamine, a polymer hole transporting material, such as polyaniline, polythiophene, polyvinylcarbazole and a mixture of poly(3,4-ethylenedioxythiophene) and polystyrenesulfonic acid, a polythiophene oligomer material, inorganic materials, such as Cu₂O, Cr₂O₃, Mn₂O₃, FeOₓ (x≦0.1) , NiO, CoO, Pr₂O₃, Ag₂O, MoO₂, Bi₂O₃, ZnO, TiO₂, SnO₂, ThO₂, V₂O₅, Nb₂O₅, Ta₂O₅, MoO₃, WO₃ and MnO₂, and other known hole transporting materials.

Examples of a solvent for dissolving or dispersing the hole transporting material include toluene, xylene, anisole, dimethoxybenzene, tetralin, cyclohexanol, acetone, methyl ethyl ketone, methyl isobutyl ketone, cyclohexanone, methanol, ethanol, isopropyl alcohol, ethyl acetate, butyl acetate, water, and mixtures thereof.

The solution or dispersion of the hole transporting material may contain a surfactant, an antioxidant, a viscosity modifier, an ultraviolet ray absorbent and the like depending on necessity, and examples of the viscosity modifier used include polystyrene and polyvinylcarbazole.

Examples of the forming method of the hole transporting layer 7 include a wet method, such as spin coating, bar coating, wire coating, slit coating, spray coating, curtain coating, flow coating, relief printing, relief reverse offset printing, ink jet printing and nozzle printing, and a vapor deposition method, such as resistance heating vapor deposition, electron beam vapor deposition, reactive vapor deposition, ion plating and sputtering, which may be selected depending on the materials used in the hole transporting layer 7.

An intermediate layer may be formed on the hole transporting layer 7. Examples of a material used in the intermediate layer 7 include a polymer containing an aromatic amine, such as polyvinylcarbazole or a derivative thereof, a polyarylene derivative having an aromatic amine on a side chain or a main chain thereof, an arylamine derivative and a triphenyldiamine derivative. The material may be dissolved or dispersed in a solvent, and may be formed into a layer by a coating method using spin coating or the like or a relief printing method.

The organic luminescent layer 8 is formed by coating an organic luminescent ink on the hole transporting layer 7, and the organic luminescent ink contains a low molecular weight luminescent material that has no repeating structure, which is a functional material for the organic luminescent layer 8 emitting red, green or blue light on application of a voltage, and a polymer material having a repeating structure, which are dissolved or dispersed in a solvent. The low molecular weight luminescent material preferably has a molecular weight of from 100 to 1,000.

The organic luminescent layer 8 is formed by attaching the organic luminescent ink (which may be hereinafter referred to as an ink), which contains the low molecular weight luminescent material dissolved or dispersed in a solvent, onto the hole transporting layer 7 by a nozzle printing method and then drying. The solvent for the ink is preferably xylene, and examples of the solvent for forming the hole transporting layer 7 described above may also be used. The thickness of the luminescent layer may be in a range of from 0.01 to 0.1 μm, and preferably from 0.03 to 0.1 μm. The luminescent efficiency tends to decrease when the thickness is outside the range.

Examples of the low molecular weight luminescent material that has no repeating structure used in the organic luminescent layer 8, i.e., the organic luminescent material used in the organic luminescent layer, include a 9,10-diarylanthracene derivative, pyrene, coronene, perylene, rubrene, 1,1,4,4-tetraphenylbutadiene, tris(8-quinolinolate) aluminum complex, tris(4-methyl-8-quinolinolate) aluminum complex, bis(8-quinolinolate) zinc complex, tris(4-methyl-5-trifluoromethyl-8-quinolinolate) aluminum complex, tris(4-methyl-5-cyano-8-quinolinolate) aluminum complex, bis(2-methyl-5-trifluoromethyl-8-quinolinolate)[4-(4-cyanophenyl)phenolate] aluminum complex, bis(2-methyl-5-cyano-8-quinolinolate)[4-(4-cyanophenyl)phenolate] aluminum complex, tris(8-quinolinolate) scandium complex, bis[8-(p-tosyl)aminoquinoline] zinc complex, bis[8-(p-tosyl)aminoquinoline] cadmium complex, 1,2,3,4-tetraphenylcyclopentadiene, pentaphenylcyclopentadiene, poly-2,5-diheptyloxy-p-phenylenevinylene, a coumarin fluorescent material, a perylene fluorescent material, a pyran fluorescent material, an anthrone fluorescent material, a porphyrin fluorescent material, a quinacridone fluorescent material, an N,N′-dialkyl-substituted quinacridone fluorescent material, a naphthalimide fluorescent material, an N,N′-diaryl-substituted pyrrolopyrrole fluorescent material, and a phosphorescent material, such as an Ir complex.

Examples of the low molecular weight luminescent material that is used in the organic luminescent layer 8 emitting red light include tris(8-quinolinol) aluminum (Alq₃) as a host material having DCM (4-dicyanomethylene-6-(p-dimethylaminostyryl)-2-methyl-4H-pyran) and DCJTB (4-dicyanomethylene-6-(p-dimethylaminostyryl)-2-(t-butyl)-4H-pyran, which are pyran compounds as dopants, added thereto in a doping concentration of 2%, respectively. The low molecular weight luminescent material is dissolved in a solvent to form an ink.

The concentration of the low molecular weight luminescent material in the ink may be in a range of from 0.1 to 5.0% by weight, and preferably from 0.5 to 1.5% by weight. When the concentration is from 0.1 to 5.0% by weight, the thickness of the film on coating by nozzle printing may not be too large to maintain the pattern accuracy on nozzle print coating. The weight of the low molecular weight luminescent material herein means the total weight of the host material and the dopants shown above.

Examples of the low molecular weight luminescent material that is used in the organic luminescent layer 8 emitting green light include Alq₃ or 2,2′,2″-(1,3,5-benzentriyl)tris(1-phenyl-1H-benzoimidazole) (TPBi) as a host material having tris(2-(p-tolyl)pyridine) iridium(III) (Ir(mppy)₃) as a dopant added thereto in a doping concentration of 4%, respectively. The low molecular weight luminescent material is dissolved in a solvent to form an ink.

The concentration of the low molecular weight luminescent material in the ink may be in a range of from 0.1 to 5.0% by weight, and preferably from 0.5 to 1.5% by weight. The weight of the low molecular weight luminescent material herein means the total weight of the host material and the dopants shown above.

Examples of the low molecular weight luminescent material that is used in the organic luminescent layer 8 emitting blue light include Alq₃ as a host material having DPVBi (4,4′-bis(2,2′-diphenylvinyl)biphenyl) and Zn(BOX)₂(2-(O-hydroxyphenyl)benzothiazole zinc complex) as dopants added thereto in a doping concentration of 2%, respectively.

The low molecular weight luminescent material is dissolved in a solvent to form an ink. The concentration of the low molecular weight luminescent material in the ink may be in a range of from 0.1 to 5.0% by weight, and preferably from 0.5 to 1.5% by weight.

Examples of the nonconductive polymer material mixed in the organic luminescent ink include polyethylene, polypropylene, polystyrene, polyvinyl chloride, polymethyl methacrylate, an ABS resin, polyamide, polyacetal, polycarbonate, polyphenylene ether, polyethylene terephthalate, polybutylene terephthalate, polysulfone, polyether sulfone, polyphenylene sulfide, polyarylate, polyimide, polyamideimide, polyetherimide, polytetrafluoroethylene, a cyclic olefin copolymer, and copolymers of these polymer materials, and polystyrene, polymethyl methacrylate and polycarbonate are preferably used.

The nonconductive polymer material preferably does not react with the low molecular weight luminescent material to be mixed and preferably has a weight average molecular weight of from 10,000 to 1,000,000. If a conductive polymer material is used, the carriers may be injected preferentially to the conductive polymer, and may migrate in the luminescent layer without contribution to the low molecular weight luminescent material, and thus the luminescent efficiency may be deteriorated.

The nonconductivity referred herein means a carrier mobility of less than 1.0×10⁻⁷ cm²/Vs, and a polymer having a carrier mobility of less than 1.0×10⁻⁷ cm/Vs may be preferably used as the nonconductive polymer material. However, the aforementioned advantages may be obtained by the use of a polymer having a carrier mobility that is lower than the carrier mobility of the low molecular weight luminescent material, and thus a polymer having a carrier mobility of 1.0×10⁻⁷ cm/Vs or more may be used when it is lower than the carrier mobility of the low molecular weight luminescent material.

The mixing ratio of the nonconductive polymer material is from 0.001 to 0.05 in terms of weight ratio with respect to the low molecular weight luminescent material in the solution. The weight of the low molecular weight luminescent material herein means the total weight of the host material and the dopants shown above. When the weight ratio is in the range, a stable organic luminescent layer may be formed as a flat film while preventing the materials from being aggregated in the drying step due to the binding effect of the nonconductive polymer material. When the weight ratio exceeds 0.05, reduction of the conductivity due to the nonconductive polymer material increases the voltage that is necessary for providing a target luminance and deteriorates the luminescent efficiency. When the weight ratio is less than 0.001, the advantage of the nonconductive polymer material may not be obtained, whereby the luminescent material maybe aggregated, and the organic luminescent layer may not be flat, which deteriorates the luminescent efficiency.

The nonconductive polymer material preferably has a weight average molecular weight in a range of from 10,000 to 1,000,000, and a mixture of the nonconductive polymer materials having different molecular weights may also be used. In the case where the nonconductive polymer materials having different molecular weights are mixed, a polymer material having a molecular weight outside the aforementioned range may be mixed, but at least one of the nonconductive polymer material having a molecular weight within the range is preferably contained. When the molecular weight of the nonconductive polymer material is less than 10,000, there are some cases where a uniform luminescent layer may not be formed.

When the molecular weight thereof exceeds 1,000,000, on the other hand, there are some cases where the viscosity of the ink is excessively increased to fail to coat the ink by a nozzle printing method, and the thickness of the coated film becomes too large to lower the conductivity of the organic luminescent medium layer, which may deteriorate the luminescent efficiency.

The nonconductive polymer material preferably has a glass transition point (Tg) of 100° C. or more. In general, a polymer having a larger molecular weight has a higher Tg, and in this point of view, the nonconductive polymer material preferably has a weight average molecular weight of from 10,000 to 1,000,000. When the Tg is less than 100° C., there are some cases where the nonconductive polymer material is fluidized on heating in the drying step after coating the organic luminescent ink, and the low molecular weight luminescent material is aggregated due to reduction of the dispersibility of the low molecular weight luminescent material, which may cause luminescent spots as luminescent defects.

Examples of the nonconductive polymer material having a high Tg include polystyrene, polymethyl methacrylate and polycarbonate. A copolymer or a mixture of the polymer having a Tg of 100° C. or more and a nonconductive polymer material having a Tg of less than 100° C. may also be used when the copolymer or the mixture has a Tg of 100° C. or more.

Examples of the solvent used in the ink containing the organic luminescent material include xylene. Xylene exhibits good solubility in a lot of aromatic compounds and organic metal complexes that are used as a low molecular weight luminescent material, and has good discharge property on nozzle printing. The use of xylene in the ink composition of the low molecular weight luminescent material for the organic luminescent layer may simplify the drying step, and thus the influence of the residual solvent may be suppressed to prevent the luminescent efficiency from being deteriorated.

In addition to xylene, such a solvent may be added to form a mixed solvent as toluene, mesitylene, cumene, anisole, methylanisole, p-cymene, tetralin, cyclohexylbenzene, methylnaphthalene, cyclohexanone, dimethoxybenzene, methyl benzoate, ethyl benzoate, water, ethanol, acetone, methyl ethyl ketone, methyl isobutyl ketone, methanol, isopropyl alcohol, cyclohexanol, ethyl acetate and butyl acetate. For enhancing the coating property, such an additive is preferably added in an appropriate amount as a surfactant, an antioxidant, a viscosity modifier and an ultraviolet ray absorbent.

In the case where a nozzle printing method is employed, the viscosity at 25° C. of the ink for the organic luminescent layer 8 of the embodiment is preferably 10 mPa·s or less, and more preferably from 1 to 3 mPa·s. When the viscosity of the ink exceeds 10 mPa·s, a favorable liquid column may not be formed on discharging the ink, and thus the coating operation is difficult to be performed due to clogging of the nozzle.

Examples of the electron transporting material used in the electron transporting layer include an oxadiazole derivative, such as 2-(4-biphenylyl)-5-(4-t-butylphenyl)-1,3,4-oxadiazole and 2,5-bis(1-naphthyl)-1,3,4-oxadiazole, bis(10-hydroxybenzo[h]quinolinolate) beryllium complex and a triazole compound. The electron transporting material maybe doped with an alkali metal or an alkaline earth metal having a small work function, such as sodium, barium and lithium, in a small amount, thereby forming an electron injection layer.

Examples of the forming method of the electron transporting layer include a wet method, such as spin coating, bar coating, wire coating, slit coating, spray coating, curtain coating, flow coating, relief printing, relief reverse offset printing, ink jet printing and nozzle printing, and a vapor deposition method, such as resistance heating vapor deposition, electron beam vapor deposition, reactive vapor deposition, ion plating and sputtering, which may be selected depending on the materials used.

Subsequently, the counter electrode 6 is formed. In the case where the second electrode is used as a cathode, a substance having a small work function, i.e., having a high electron injection efficiency to the organic luminescent medium layer 5, may be used. Specifically, for example, a metal simple material, such as Mg, Al and Yb, may be used, and Al or Cu having high stability and conductivity may be accumulated on the interface in contact with the luminescent medium, with Li or a compound, such as lithium oxide and LiF, having a thickness of approximately 1 nm intervening therebetween. For achieving both the electron injection efficiency and the stability, an alloy system of at least one metal having a small work function, such as Li, Mg, Ca, Sr, La, Ce, Er, Eu, Sc, Y and Yb, and a stable metal element, such as Ag, Al and Cu, may also be used.

Specifically, such an alloy may be used as MgAg, AlLi and CuLi. In the case where a so-called top emission structure where light is emitted on the side of the second electrode is produced, a material having light transmissibility is preferably selected. In this case, Li or Ca having a small work function may be provided to a small thickness, and then a metal composite oxide, such as ITO (indium tin composite oxide), indium zinc composite oxide and zinc aluminum composite oxide, may be accumulated. In alternative, the organic luminescent medium layer may be doped with a metal having a small work function, such as Li and Ca, in a small amount, and then a metal oxide, such as ITO, maybe accumulated.

Examples of the forming method of the counter electrode 6 include a resistance heating vapor deposition method, an electron beam vapor deposition method, a reactive vapor deposition method, an ion plating method and a sputtering method, depending on the material used. The thickness of the second electrode is not particularly limited and is preferably from 10 to 1,000 nm. In the case where the second electrode is used as a light transmissive electrode layer, the thickness of the metal material, such as Ca and Li, is preferably from 0.1 to 10 nm.

Subsequently, a passivation layer may be formed between the counter electrode and a sealant, for example, on the counter electrode. Examples of the material of the passivation layer include a metal oxide, such as silicon oxide and aluminum oxide, a metal fluoride, such as aluminum fluoride and magnesium fluoride, a metal nitride, such as silicon nitride, aluminum nitride and carbon nitride, a metal oxynitride, such as silicon oxynitride, and a metal carbide, such as silicon carbide, and a laminated film with a polymer resin film, such as an acrylic resin, an epoxy resin, a silicone resin and a polyester resin, may also be used depending on necessity. In view of the barrier property and the transparency, silicon oxide (SiOₓ), silicon nitride (SiNₓ) and silicon oxynitride (SiOₓN_{y}) are preferably used, and furthermore a multilayer film or a gradient film having various film densities may be provided by changing the film forming conditions.

Examples of the forming method of the passivation layer include a resistance heating vapor deposition method, an electron beam vapor deposition method, a reactive vapor deposition method, an ion plating method, a sputtering method and a CVD method, and in view of the barrier property and the transparency, a CVD method is preferably employed. Examples of the CVD method include a thermal CVD method, a plasma CVD method, a catalyst CVD method and a VUV-CVD method.

Examples of the reaction gas used in the CVD method include an organic silicone compound, such as monosilane, hexamethyldisilazane (HMDS) and tetraethoxysilane, to which a gas, such as N₂, O₂, NH₃, H₂ and N₂O, may be added depending on necessity. For example, the density of the film may be changed by changing the flow rate of silane, and hydrogen or carbon may be added to the film by selecting the reaction gas used. The thickness of the passivation layer may vary depending on the step height of the electrode of the organic EL device, the height of the partition wall of the substrate, the barrier property required, and the like, and is generally approximately from 0.01 to 10 μm.

The organic luminescent material may be easily deteriorated with water and oxygen in the air, and thus a sealant is provided for shielding the organic luminescent medium layer from the exterior. The sealant may be provided by forming a resin layer on the sealant. The sealant is necessarily such a substrate that has low permeability to water and oxygen.

Examples of the material for the sealant include ceramics, such as alumina, silicon nitride and boron nitride, glass, such as non-alkali glass and alkali glass, quartz, a metal foil, such as aluminum and stainless steel, and a moisture proof film. Examples of the moisture proof film include a film containing a plastic substrate having SiOx formed on both surfaces thereof by a CVD method, and a polymer film containing a film having a small permeability having a film having water absorbability laminated thereon or a water absorbing agent coated thereon. The moisture proof film preferably has a water vapor permeability of 1.0×10⁻⁶ g/m²/day or less.

Examples of the material for the resin layer include a photocurable adhesive resin, a thermosetting adhesive resin and a two-component curable adhesive resin, which are formed of an epoxy resin, an acrylic resin, a silicone resin or the like, an acrylic resin, such as an ethylene-ethyl acrylate (EEA) polymer, a vinyl resin, such as an ethylene-vinyl acetate (EVA) polymer, a thermoplastic resin, such as polyamide and synthetic rubber, and a thermoplastic adhesive resin, such as an acid-modified product of polyethylene or polypropylene.

Examples of the forming method of the resin layer on the sealant include a solvent solution method, an extrusion lamination method, a hot-melt method, a calendering method, a nozzle coating method, a screen printing method, a vacuum lamination method and a heat roll lamination method. A material having moisture absorbing property or oxygen absorbing property may be contained depending on necessity. The thickness of the resin layer formed on the sealant may be arbitrarily determined depending on the size and the shape of the organic EL device to be sealed and is preferably from 5 to 500 μm.

The resin layer is formed on the sealant herein, but may be formed directly on the side of the organic EL device.

Finally, the organic EL device and the sealant are adhered in a sealing chamber. In the case where the sealant has a two-layer structure containing the sealant and the resin layer, and the resin layer is formed of a thermoplastic resin, the adhering operation is preferably performed only by adhesion under pressure with a heated roll. In the case where a thermosetting adhesive resin or a photocurable adhesive resin is used, it is preferred that the assembly formed by adhesion under pressure with a roll or a flat plate is subjected to photocuring or thermal curing.

In the case where a concave substrate having a shape that covers the organic EL device is used as the sealant, the resin layer may be formed only on the portion where the substrate of the organic EL device and the concave sealant are in contact with each other, and then the organic EL device and the sealant may be adhered for sealing the organic EL device. In this case, the passivation layer and the resin layer may not be formed on the organic EL device.

An example of the production method of the organic EL device 1 having the aforementioned structure will be described below. On the light transmissive substrate 2 having a thin film transistor formed thereon, the pixel electrode 3 is formed to make contact with the thin film transistor. Specifically, an ITO film is formed over the entire surface of the light transmissive substrate 2 by a sputtering method and then subjected to exposure and development by photolithography technique, thereby covering the necessary portion to be the pixel electrode 3 with a photoresist. The unnecessary portion is then removed by etching the ITO film with an acid solution, and thereby plural pixel electrodes 3 disposed with a prescribed interval are formed.

Subsequently, the partition wall 4 is formed among the pixel electrodes 3. Specifically, a photoresist is coated on the light transmissive substrate 2 or the pixel electrodes 3 and then subjected to exposure and development by photolithography technique, thereby making the photoresist to remain among the pixel electrodes 3. Thereafter, the photoresist is cured by baking.

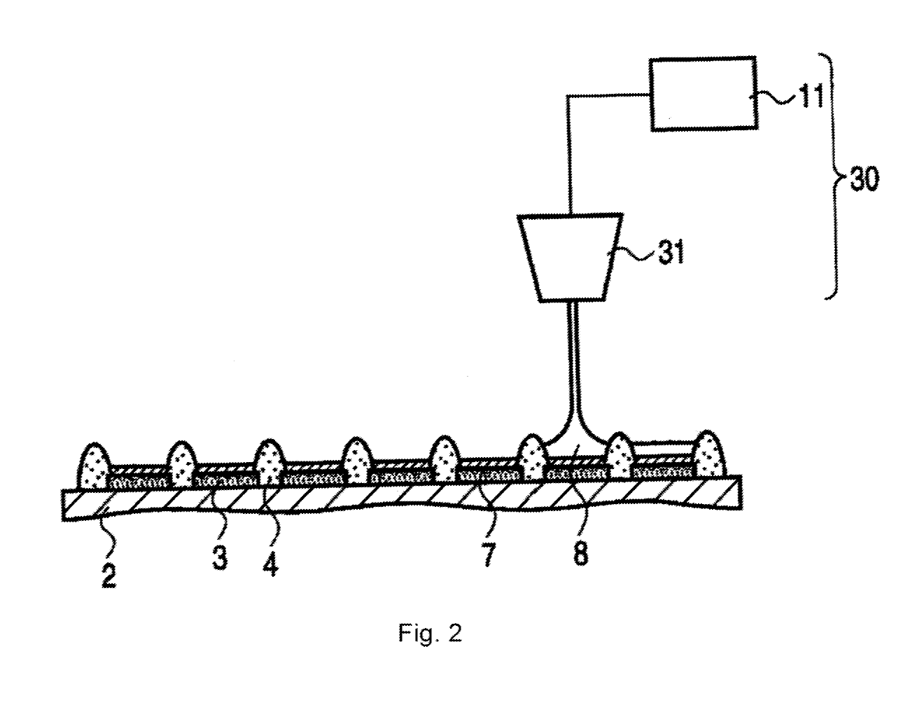

The ink of the hole transporting material is then coated on the pixel electrode 3 by nozzle printing using a nozzle printing apparatus 30 shown in FIG. 2, thereby forming the hole transporting layer 7. The nozzle printing apparatus 30 has an ink tank 11 that houses the organic luminescent ink, and an ink nozzle 31 that discharges a liquid column of the ink. A liquid column of the ink is discharged from the ink nozzle 31 to the surface of the pixel electrode 3. The ink attached to the pixel electrode 3 is flattened due to the low viscosity thereof within the area partitioned by the partition wall 4. Thereafter, the ink is dried and fixed.

The nozzle printing apparatus 30 may be a multi-nozzle printing apparatus that has two or more of the nozzles 31. The multi-nozzle printing apparatus may enhance the productivity.

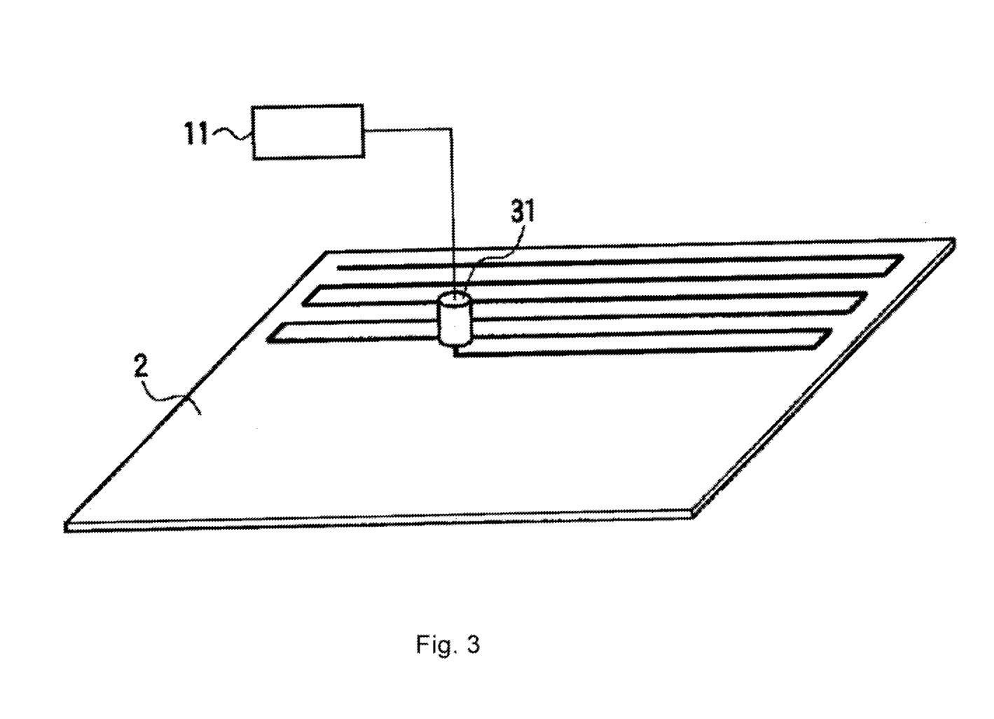

FIG. 3 is a perspective view of the step of forming the hole transporting layer 7 by using the nozzle printing apparatus 30 shown in FIG. 2. In FIG. 3, the partition wall 4 is not shown, and the ink for the hole transporting layer is discharged along the partition wall 4 disposed in the longitudinal direction (which is the horizontal direction shown in FIG. 3).

After forming the hole transporting layer 7, the organic luminescent layer 8 is formed on the hole transporting layer 7 by the same nozzle printing method. As having been described above, the material for forming the organic luminescent layer 8 is a mixture of the low molecular weight luminescent material and the nonconductive polymer material.

Subsequently, the counter electrode 6 is formed on the organic luminescent layer 8 by a vapor deposition method, such as a resistance heating vapor deposition method. Finally, for protecting the pixel electrodes 3, the organic luminescent layer 5 and the counter electrodes 6 from oxygen and water in the air, they are filled with a resin layer 9 and covered with a sealing substrate 10, thereby completing the organic EL device 1.

According to the organic EL device 1 having the aforementioned structure and the method for producing the organic EL device 1, a low molecular weight luminescent material may be applied to a nozzle printing method, and the luminescent layer may be stabilized without deterioration of the luminescent efficiency.

The invention is not limited to the aforementioned embodiments, and various changes maybe applied thereto in such a range that does not deviate from the substance of the invention. For example, a hole blocking layer, a hole injection layer, an electron injection layer and an electron blocking layer may be provided. The hole injection layer and the electron blocking layer have such a function as similar to the hole transporting layer 7 that holes injected from the pixel electrode 3 are directed to the counter electrode 6 and preventing electrons from being directed to the pixel electrode 3 while transmitting holes. The hole blocking layer, the electron transporting layer and the electron injection layer have such a function that electrons injected from the counter electrode 6 are directed to the pixel electrode 3 and preventing holes from being directed to the counter electrode 6 while transmitting electrons.

A thin film of lithium fluoride or the like may be provided between the counter electrode 6 and the organic luminescent medium layer 5. For patterning the counter electrode 6, a vapor deposition mask of a metal film, a ceramic film or the like may be used. The partition wall 4 is formed among the pixel electrodes 3 in the embodiment, but such a structure may be employed that the partition wall 4 is not provided.

### EXAMPLE

The invention will be described in more detail with reference to Examples and Comparative Examples below. The invention is not limited to the following description. Production of Device

As shown in FIG. 1, on the light transmissive substrate 2 (white plate glass, 100 mm in length×100 mm in width×0.7 mm in thickness), the pixel electrodes 3 each having a strip form of 80 μm in width and 0.15 μm in thickness were formed with an interval of 80 μm by a sputtering method. The pixel electrodes 3 had a surface roughens Ra of 20 nm within an arbitrary plane of 200 μm². The partition wall 4 had a width of 90 mat the lower end in contact with the light transmissive substrate 2, a width of 45 μm at the upper end, and a height of 2 μm, and had a substantially trapezoidal cross sectional shape.

The partition wall 4 was formed by developing by a photolithography technique and then baking at 200° C. for 60 minutes. The hole transporting layer 7 was formed in such a manner that a polyarylene derivative as a hole transporting material was dissolved in xylene to form an ink having a concentration of 3.0% by weight, which was coated within the partition wall by a nozzle printing method and then dried at 200° C. for 10 minutes.

In the organic luminescent layer 8, 2,2′,2″-(1,3,5-benzentriyl)tris(1-phenyl-1H-benzoimidazole) (TPBi) as a host material and tris(2-(p-tolyl)pyridine) iridium(III) (Ir(mppy)₃) as a dopant were used as a low molecular weight luminescent material used in a pixel emitting green light. The nonconductive polymer material to be mixed with the low molecular weight luminescent material was polystyrene. The mixture of the low molecular weight luminescent material and the nonconductive polymer material was dissolved in xylene to form a solution having a concentration of 2% by weight, which was coated on the hole transporting layer 7 by a nozzle printing method and then dried in an inert gas atmosphere at 130° C. for 30 minutes, thereby forming the organic luminescent layer 8 having a thickness of 70 nm. The composition of the ink for the luminescent layer will be described in Examples and Comparative Examples below. Thereafter, a multilayer film of LiF/Al=0.5 nm/150 nm was formed as the cathode 6 by vapor deposition. The sealing substrate was then adhered to provide the organic EL device 1.

### Evaluation Methods

The organic EL devices produced in Examples and Comparative Examples were evaluated in the following manners. Flatness

After forming the luminescent layer 8 on the hole transporting layer 7, the thickness profile of the luminescent layer 8 was measured, and the ratio of the width (W2) of the luminescent layer 8 where the thickness thereof was larger by 10 nm or less from the minimum thickness thereof, with respect to the open width (W1) of the partition wall ((W2/W1)×100 (%)) was calculated.

### Luminescent Efficiency

The luminescent efficiency of the device on application of a voltage of 7 V was measured.

### Lifetime

The device was subjected to light emission at a constant electric current for a luminance of 1,000 cd/m², and the half-life period of the luminance was measured.

### Example 1

The low molecular weight luminescent material (host/dopant) and the nonconductive polymer material (weight average molecular weight Mw: 250,000) constituting the luminescent layer 8, and the weight mixing ratio thereof are shown below.

TPBi/Ir(mppy)₃/polystyrene (PS)=0.94/0.06/0.05

The materials in the aforementioned ratio were dissolved in xylene to form an ink having a concentration of 2.0% by weight, and an organic EL device was produced in the aforementioned manner and evaluated in the aforementioned manner.

### Example 2

An organic EL device was produced in the same manner as in Example 1 except that the mixing ratio was changed as follows, and evaluated in the aforementioned manner.

TPBi/Ir(mppy)₃/polystyrene (PS)=0.94/0.06/0.01

### Example 3

An organic EL device was produced in the same manner as in Example 1 except that the mixing ratio was changed as follows, and evaluated in the aforementioned manner.

TPBi/Ir(mppy)₃/polystyrene (PS)=0.94/0.06/0.001

### Examples 4 and 5

An organic EL devices were produced in the same manner as in Example 1 except that the Mw of the polystyrene was changed as shown in Table 1, and evaluated in the aforementioned manner.

### Example 6

An organic EL device was produced in the same manner as in Example 1 except that the material and the mixing ratio were changed as follows, and evaluated in the aforementioned manner.

TPBi/Ir(mppy)₃/polymethyl methacrylate (PMMA, Mw: 250,000)=0.94/0.06/0.010

### Example 7

An organic EL device was produced in the same manner as in Example 1 except that the material and the mixing ratio were changed as follows, and evaluated in the aforementioned manner.

TPBi/Ir(mppy)₃/polycarbonate (PC, Mw: 250,000)=0.94/0.06/0.010

### Comparative Example 1

An organic EL device was produced in the same manner as in Example 1 except that the mixing ratio was changed as follows, and evaluated in the aforementioned manner.

TPBi/Ir(mppy)₃/polystyrene (PS)=0.94/0.06/0.100

### Comparative Example 2

An organic EL device was produced in the same manner as in Example 1 except that the mixing ratio was changed as follows, and evaluated in the aforementioned manner.

TPBi/Ir(mppy)₃/polystyrene (PS)=0.94/0.06/0.300

### Comparative Example 3

An organic EL device was produced in the same manner as in Example 1 except that the mixing ratio was changed as follows, and evaluated in the aforementioned manner.

TPBi/Ir(mppy)₃/polystyrene (PS)=0.94/0.06/0.500

### Comparative Example 4

An organic EL device was produced in the same manner as in Example 1 except that the partition wall 4 was not formed, and an ink containing only the low molecular weight luminescent material without the polymer material mixed therein was coated by a spin coating method to form the luminescent layer, and evaluated in the aforementioned manner.

### Comparative Example 5

An organic EL device was produced in the same manner as in Example 1 except that the polymer material was not mixed, but only the low molecular weight luminescent material was used, and evaluated in the aforementioned manner.

### Comparative Examples 6 and 7

An organic EL devices were produced in the same manner as in Example 1 except that the Mw of the polystyrene was changed as shown in Table 1, and evaluated in the aforementioned manner. Comparative Example 8

An organic EL devices were produced in the same manner as in Example 1 except that polyvinyl carbazole (PVK, Mw: 250,000) as a conductive polymer was mixed as the polymer material, and evaluated in the aforementioned manner.

The evaluation results of Examples 1 to 7 and Comparative Examples 1 to 8 are shown in Table 1 below.

TABLE 1

| | Mixing weight ratio | | | | Molecular weight | Discharge | | Luminescent | |
|---|---|---|---|---|---|---|---|---|---|
| | Conductive | Nonconductive | Nonconductive | Nonconductive | of polymer | property | | efficiency | Half life |
| | polymer | polymer | polymer | polymer | material | on nozzle | Flatness | (cd/A) | of initial |
| | PVK | PS | PMMA | PC | Mw | printing | (%) | at 7 V | luminance |
| Example 1 | — | 0.050 | — | — | 250,000 | good | 95 | 20.0 | 119 |
| Example 2 | — | 0.010 | — | — | 250,000 | good | 90 | 20.0 | 120 |
| Example 3 | — | 0.001 | — | — | 250,000 | good | 80 | 20.0 | 118 |
| Example 4 | — | 0.050 | — | — | 10,000 | good | 82 | 20.0 | 118 |
| Example 5 | — | 0.050 | — | — | 1,000,000 | good | 95 | 20.0 | 119 |
| Example 6 | — | — | 0.010 | — | 250,000 | good | 90 | 19.9 | 119 |
| Example 7 | — | — | — | 0.010 | 250,000 | good | 90 | 19.8 | 119 |
| Comparative | — | 0.100 | — | — | 250,000 | good | 88 | 18.0 | 84 |
| Example 1 | | | | | | | | | |
| Comparative | — | 0.300 | — | — | 250,000 | good | 56 | 17.2 | 53 |
| Example 2 | | | | | | | | | |
| Comparative | — | 0.500 | — | — | 250,000 | good | 25 | 15.2 | 12 |
| Example 3 | | | | | | | | | |
| Comparative | — | — | — | — | — | spin | 100 | 20.0 | 121 |
| Example 4 | | | | | | coating | | | |
| Comparative | — | — | — | — | — | good | 65 | 20.0 | 79 |
| Example 5 | | | | | | | | | |
| Comparative | — | 0.050 | — | — | 8,000 | good | 66 | 20.0 | 85 |
| Example 6 | | | | | | | | | |
| Comparative | — | 0.050 | — | — | 1,200,000 | bad (not | — | — | — |
| Example 7 | | | | | | discharged) | | | |
| Comparative | 0.050 | — | — | — | 250,000 | good | 95 | 12.8 | 28 |
| Example 8 | | | | | | | | | |

As shown in Table 1, Examples 1 to 7 demonstrate that the addition of the nonconductive polymer material in an amount of 0.05 or less per 1 of the low molecular weight luminescent material enhances the flatness of the film as equivalent to the film formed by spin coating in Comparative Example 4 and prevents the luminescent efficiency and the lifetime from being deteriorated. In Comparative Examples 1 to 3 where the nonconductive polymer material is added in an amount of more than 0.05 per 1 of the low molecular weight luminescent material, however, deterioration of the luminescent efficiency and the lifetime is found due to reduction of the flatness and reduction of the conductivity. In Comparative Examples 6 and 7 where the molecular weight of the nonconductive polymer material is outside the range of from 10,000 to 1,000,000, the flatness is deteriorated, or the discharge property on nozzle printing is deteriorated. In Comparative Example 8 where a conductive polymer is mixed, the luminescent efficiency is deteriorated although the flatness of the film is increased. Thus, the addition of the nonconductive polymer material prevents deterioration of the luminescent efficiency and the lifetime while maintaining the carrier balance.

According to the invention, an organic EL device may be provided that has a luminescent layer formed by nozzle printing with an ink composition containing a low molecular weight luminescent material and a polymer material, and prevents the luminescent efficiency and the lifetime thereof from being deteriorated.

What is claimed is:

1. An ink composition for forming an organic layer of an organic electroluminescence device,
in which an organic luminescent layer is the organic layer, the ink composition comprising:
at least one low molecular weight luminescent material that has no repeating structure; and
at least one polymer material having a repeating structure, the polymer material mixed with the low molecular weight luminescent material,
the polymer material is a nonconductive material, and
a weight ratio of the polymer material with respect to the low molecular weight luminescent material is from 0.001 to 0.05.

2. The ink composition according to claim 1, wherein the polymer material has a weight average molecular weight of from 10,000 to 1,000,000.

3. The ink composition according to claim 1, wherein the polymer material has a glass transition point of 100° C. or more.

4. The ink composition according to claim 1, wherein the polymer material is polystyrene, polymethyl methacrylate or polycarbonate.

5. An organic electroluminescence device comprising an anode, a cathode and plural organic layers intervening between the anode and the cathode,
the plural organic layers including an organic luminescent layer containing at least one low molecular weight luminescent material that has no repeating structure and at least one polymer material having a repeating structure, the polymer material mixed with the low molecular weight luminescent material,
the polymer material being a nonconductive material, and
a weight ratio of the polymer material with respect to the low molecular weight luminescent material being from 0.001 to 0.05.

6. The organic electroluminescence device according to claim 5, wherein the polymer material has a weight average molecular weight of from 10,000 to 1,000,000.

7. The organic electroluminescence device according to claim 5, wherein the polymer material has a glass transition point of 100° C. or more.

8. The organic electroluminescence device according to claim 5, the polymer material is polystyrene, polymethyl methacrylate or polycarbonate.

9. A method for producing an organic electroluminescence device, comprising:
a coating step of coating the ink composition of claim 1 by a nozzle printing method on a pixel substrate partitioned into pixels with a partition wall; and
a solvent removing step of removing an ink solvent contained in the ink composition to form an organic layer for the organic electroluminescence device.

10. The method for producing an organic electroluminescence device according to claim 9, wherein the solvent removing step includes a drying step of heating in a nitrogen atmosphere at a heating temperature of 100° C. or more.

11. A method for producing an organic electroluminescence device, comprising:
a coating step of coating the ink composition of claim 2 by a nozzle printing method on a pixel substrate partitioned into pixels with a partition wall; and
a solvent removing step of removing an ink solvent contained in the ink composition to form an organic layer for the organic electroluminescence device.

12. The method for producing an organic electroluminescence device according to claim 11, wherein the solvent removing step includes a drying step of heating in a nitrogen atmosphere at a heating temperature of 100° C. or more.

13. A method for producing an organic electroluminescence device, comprising:
a coating step of coating the ink composition of claim 3 by a nozzle printing method on a pixel substrate partitioned into pixels with a partition wall; and
a solvent removing step of removing an ink solvent contained in the ink composition to form an organic layer for the organic electroluminescence device.

14. The method for producing an organic electroluminescence device according to claim 13, wherein the solvent removing step includes a drying step of heating in a nitrogen atmosphere at a heating temperature of 100° C. or more.

15. A method for producing an organic electroluminescence device, comprising:
a coating step of coating the ink composition of claim 4 by a nozzle printing method on a pixel substrate partitioned into pixels with a partition wall; and
a solvent removing step of removing an ink solvent contained in the ink composition to form an organic layer for the organic electroluminescence device.

16. The method for producing an organic electroluminescence device according to claim 15, wherein the solvent removing step includes a drying step of heating in a nitrogen atmosphere at a heating temperature of 100° C. or more.
